(19) United States
(12) Patent Application Publication
(10) Pub. No.: US 2026/0205118 A1
(43) Pub. Date: Jul. 16, 2026

(54) Photoelectric Microswitch

(71) Applicant: DONGGUAN CITY KAIHUA ELECTRONICS CO.LTD, Dongguan (CN)

(72) Inventors: Fuxi WU, Dongguan (CN); Yun HUANG, Dongguan (CN)

(21) Appl. No.: 19/024,256

(22) Filed: Jan. 16, 2025

(51) Int. Cl. H03K 17/968; H03K 17/567

(52) U.S. Cl. CPC H03K 17/968; H03K 17/567; H01H 2239/022

(57) ABSTRACT

A photoelectric microswitch, comprising a mounting base (1) and a cover (2), wherein the cover covers the mounting base to form an accommodating cavity (3); a guide core (4) and a reed (5) are arranged in the accommodating cavity, the reed is located below the guide core, and an upper end of the guide core penetrates out of the cover for allowing to be pressed; the mounting base comprises a base (11) and a pedestal (12) arranged on the base; a light-emitting pair transistor assembly (7) electrically connected to a PCB is arranged inside the base, and the light-emitting pair transistor assembly comprises a light-emitting element (71) and a photosensitive element (72) which are oppositely arranged. By means of the photoelectric microswitch, automatic assembly is facilitated, and the assembly convenience and efficiency are improved.

### TECHNICAL FIELD

The utility model relates to the field of microswitches, in particular to a photoelectric microswitch.

### TECHNICAL BACKGROUND

Micro-switch is a commonly used switch mechanism, which is a contact mechanism with tiny contact spacing and quick-acting mechanism, and it is widely used in industry, electronics, machinery, metallurgy, electric power and other fields.

The working principle of microswitch is as follows: External mechanical force acts on the action reed through transmission elements (push pins, buttons, levers, rollers, etc.), and when the action reed is displaced to the critical point, it produces instantaneous action, so that the moving contact at the end of the action reed can be quickly connected or disconnected.

The existing microswitch usually adopts the way of setting the moving contact on the action reed. Before and after the action reed is pressed, the moving contact contacts with the static contact located above or below the action reed respectively, so as to realize the function of on or off. This conduction mode is influenced by the production environment. As long as there is a small foreign body falling on the contact point, the switch will not be conductive or the light press will be nonfunctional.

In order to solve the above problems, photoelectric microswitch has appeared in the market at present, which has the following two shortcomings:

(1) Assembling all parts (reed, light shield, light-emitting tube, etc.) on the same base is complicated and difficult, which is not conducive to the realization of the functions of all parts;

(2)The reed is connected with the light-blocking sheet through other parts, which not only has a short service life, but also has a limited depth of downward extension of the light-blocking sheet, so that when the position of the light-emitting pair tube is relatively low, the light-blocking sheet cannot extend downward to light-emitting pair tube for light-blocking operation; Moreover, the reed percussion sounds inconsistent and unclear, and the effect is poor.

### SUMMARY OF THE UTILITY MODEL

In view of the above shortcomings, the utility model aims to provide a photoelectric microswitch, which greatly improves the convenience of assembly, facilitates automatic assembly and improves the convenience and efficiency of assembly.

The technical scheme adopted by the utility model is as follows:

A photoelectric microswitch comprises a mounting base and a cover covering the mounting base, wherein the cover covers the mounting base to form an accommodating cavity; a guide core and a reed are arranged in the accommodating cavity, and the reed is positioned below the guide core, and the upper end of the guide core penetrates through the cover for pressing; and the photoelectric microswitch is characterized in that the mounting base comprises a base and a base arranged on the base, and a light-emitting pair tube assembly electrically connected to a PCB board is arranged in the base. The reed is installed on the base, and a light-blocking sheet for blocking the light between the light-emitting element and the photosensitive element is extended downwards, and the reed and the light-blocking sheet are connected into a whole.

As a further improvement of the utility model, an installation cavity is formed in the base, the light-emitting tube assembly is arranged in the installation cavity, and the base and the base are combined to form a longitudinal slot which is communicated with the installation cavity and is used for longitudinally inserting the light-blocking sheet.

As a further improvement of the utility model, the light-emitting tube assembly further comprises a pad, two first PIN pins welded to the light-emitting element through the pad, and two second PIN pins welded to the photosensitive element through the pad, and the two first PIN pins and the two second PIN pins are respectively electrically connected to the PCB.

As a further improvement of the utility model, the two first PIN pins and the two second PIN pins are respectively vertically inserted into the PCB.

As a further improvement of the utility model, the pad is provided with a yielding opening which is located between the light-emitting element and the photosensitive element and through which the light-blocking sheet passes.

As a further improvement of the utility model, a through hole for the first PIN pin and the second PIN pin to pass through is respectively formed on both sides of the mounting cavity.

As a further improvement of the utility model, an inner limiting slot is formed at the bottom of the bonding pad, and an inner limiting protrusion which is clamped into the inner limiting slot is convexly arranged in the mounting cavity.

As a further improvement of the utility model, a lower guide inclined plane is formed at one side of the inner limit protrusion, and an upper guide inclined plane matched with the lower guide inclined plane is formed in the inner limit clamping groove.

As a further improvement of the utility model, a one-side limiting slot is formed at one end of the bonding pad, and a one-side limiting protrusion which is clamped into the one-side limiting slot is formed at the opening of one side of the mounting cavity.

As a further improvement of the utility model, the base is provided with a limit bump located on the inner wall of the longitudinal slot side.

As a further improvement of the utility model, a strip-shaped clamping groove is formed on the base, and a strip-shaped clamping strip clamped into the strip-shaped clamping groove is formed at the bottom of the base.

As a further improvement of the utility model, two opposite ends of the base are respectively provided with a limit stop, and two opposite ends of the base are respectively provided with a limit gap for embedding the limit stop.

As a further improvement of the utility model, a first fixed terminal is arranged on the base, and the lower end of the first fixed terminal penetrates through the lower end surface of the base, and a limit part located on the upper end surface of the base is formed on the first fixed terminal, and a side opening for one end of the reed to be inserted and move up and down is formed on the limit part, and a tapping sound surface is formed at the upper end and the lower end of the side opening respectively.

As a further improvement of the utility model, a light hole is formed on the light blocking sheet.

As a further improvement of the utility model, the height of the side opening is equal to the height of the light hole.

As a further improvement of the utility model, the reed is mainly composed of an elastic piece and a tongue piece integrally formed at the lower part of the elastic piece and bent downward, and the light blocking piece is formed by bending and extending the side edge of one end of the elastic piece downward.

As a further improvement of the utility model, a second fixed terminal is arranged on the base, and the lower end of the second fixed terminal penetrates through the lower end surface of the base, and a first connecting part and a second connecting part located on the upper end surface of the base are formed on the second fixed terminal; The elastic sheet is provided with a connecting opening for the first connecting part to pass through, the outer side of the first connecting part is provided with a first clamping groove for the inner wall of the connecting opening to be clamped, and the outer side of the second connecting part is provided with a second clamping groove for the end of the tongue piece to be clamped.

The utility model has the beneficial effects that:

(1) By divide that mounting seat into at least two part, namely the base and the base, during assembly, the reed can be mounted on the base, and the light-emitting tube assembly is mount in the base, so that the assembly is more convenient and simple. At the same time, the mounting base which is divided into two parts, the base and the base, is also beneficial for the reed and the light blocking piece which are connected into a whole to play their respective roles. Specifically, the reed is used for pressing reset and pressing sound, and the light blocking piece is used for shielding light, and the pressing sound and the light blocking are carried out at the same time, so that the accuracy of the action can be significantly improved.

(2) Because the reed is connected with the light-blocking sheet into a whole, and the light-blocking sheet is formed by the downward extension of the reed, the base and the base which are separated are convenient for the light-blocking sheet to extend downward, so that the light-blocking sheet can block the light between the light-emitting element and the photosensitive element arranged in the base.

(3) The integrated structure of the reed and the light-blocking plate facilitates the light-blocking plate to extend downward to a deeper depth and facilitates the realization of the on-off function. The integrated reed and the light barrier structure form a component, but they can perform different actions and realize different functions. Compared with the split structure or the structural design that connects them with other structures, the integrated structural design can prolong the service life of the component, and the sound emitted by the reed tapping is consistent and clearer.

(4) The light-emitting tube assembly with special structural design is directly assembled in the base of the mounting seat, so that the on-off function of the micro switch is realized, and the phenomenon of poor conduction or no function due to light pressing due to foreign objects is avoided, thereby improving the on-off accuracy and stability of the micro switch and bringing great convenience to users; At the same time, it greatly improves the convenience of assembly, facilitates automatic assembly and improves the convenience and efficiency of assembly.

The above is an overview of the technical scheme of the utility model, and the following is a further explanation of the utility model with the attached drawings and specific embodiments.

### BRIEF DESCRIPTION OF DRAWINGS

FIG. 1 is an exploded view of the utility model;

FIG. 2 is a partial structural diagram of the utility model;

FIG. 3 is a schematic structural diagram of the light-emitting tube assembly in the utility model;

FIG. 4 is a schematic diagram of the bottom structure of the light-emitting tube assembly in the utility model;

FIG. 5 is a structural schematic diagram of the mounting seat in the utility model;

FIG. 6 is another structural schematic diagram of the mounting seat in the utility model;

FIG. 7 is a sectional view of the utility model;

FIG. 8 is a schematic structural diagram of the combination of the reed, the first fixed terminal and the second fixed terminal of the utility model;

FIG. 9 is a schematic diagram of the photoelectric microswitch of the utility model plugged into a PCB;

FIG. 10 is an exploded view of the installation seat in the utility model.

### EMBODIMENT

In order to further explain the technical means and effects adopted by the utility model to achieve the predetermined purpose, the specific implementation of the utility model will be described in detail with the attached drawings and preferred embodiments.

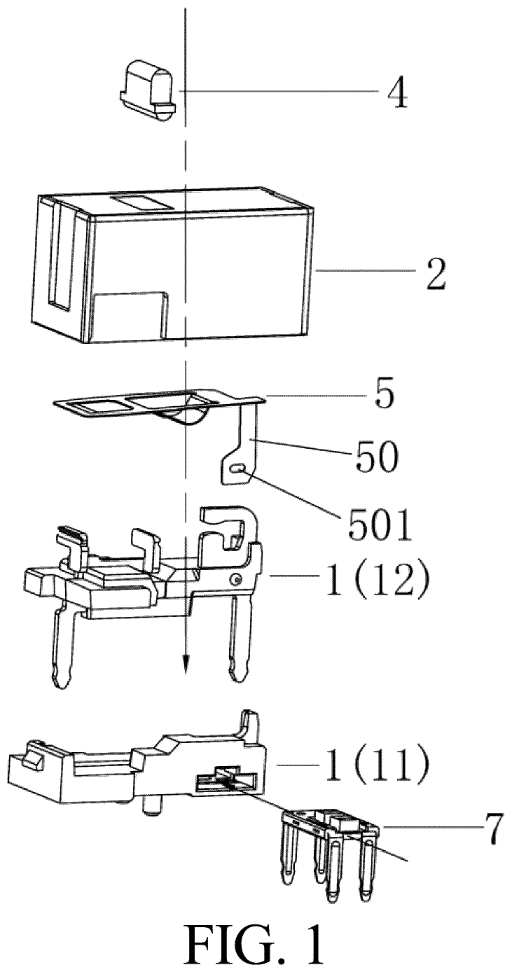

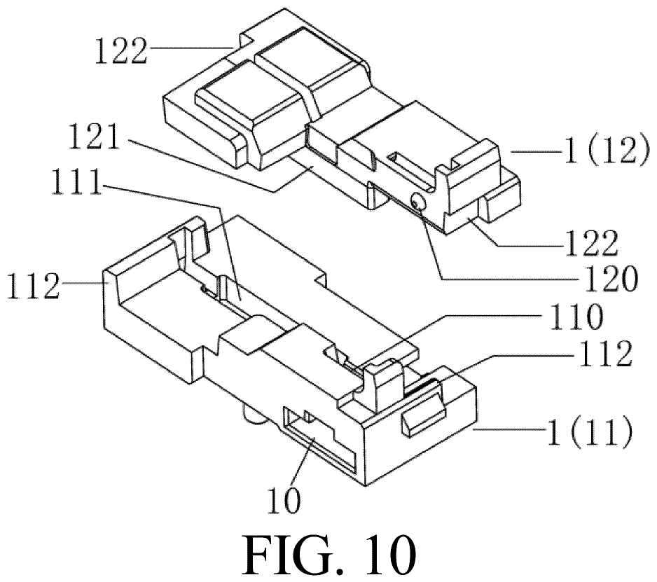

Please refer to FIG. 1 to FIG. 3. An embodiment of the utility model provides a photoelectric microswitch, which comprises a mounting seat 1 and a cover 2 covering the mounting seat 1. The cover 2 covers the mounting seat 1 to form an accommodating cavity 3. A guide core 4 and a reed 5 are arranged in the accommodating cavity 3. The reed 5 is located below the guide core 4, and the upper end of the guide core 4 passes through the cover 2 for pressing. In this embodiment, as shown in FIGS. 1 and 10, the mounting base 1 comprises a base 11 and a base 12 arranged on the base 11. A light emitting diode assembly 7 electrically connected to the PCB board 6 is arranged in the base 11, The light-emitting pair tube assembly 7 includes a light-emitting element 71 and a photosensitive element 72, which are oppositely arranged. The reed 5 is mounted on the base 12, The reed 5 extends downward and is provided with a light blocking sheet 50 for blocking the light between the light emitting element 71 and the photosensitive element 72. And the reed 5 is integrated with the light blocking sheet 50.

By dividing the mounting seat 1 into two parts (base 11 and base 12), During assembly, the reed 5 can be installed on the base 12, and the light-emitting tube assembly 7 can be installed in the base 11, which makes the assembly more convenient and simple.

At the same time, the mounting seat 1 is divided into a base 11 and a base 12, It is also beneficial for the integrated reed 5 and the light blocking sheet 50 to play their respective roles. Specifically, the reed 5 is used for press reset and press sound, and the light blocking sheet 50 is used for light shielding, and the press sound and light shielding are carried out at the same time, so that the accuracy of the action can be significantly improved.

Meanwhile, since the reed 5 is connected with the light blocking sheet 50 into a whole, and the light blocking sheet 50 is formed by extending the reed 5 downward, The base 11 and the base 12 are separated, which facilitates the downward extension of the light blocking sheet 50, so that the light blocking sheet 50 can block the light between the light emitting element 71 and the photosensitive element 72 arranged in the base 11. At the same time, the integrated structure of the reed 5 and the light blocking sheet 50 facilitates the downward extension of the light blocking sheet 50 to a deeper depth, and facilitates the realization of the on-off function. The integrated reed 5 and the light-blocking sheet 50 form a component, but they can perform different actions and realize different functions. Compared with the split structure or the structural design of connecting them with other structures, the integrated structural design of this embodiment can improve the service life of the component.

Because the light-emitting tube assembly 7 is directly assembled in the base 11, the on-off function of the microswitch is realized, and the phenomenon of poor conduction or no function due to light pressing due to foreign objects will not occur. So as to improve the conduction accuracy and stability of the microswitch and bring great convenience to users; At the same time, it greatly improves the convenience of assembly, facilitates automatic assembly and improves the convenience and efficiency of assembly.

When the guide core 4 is pressed down, the guide core 4 drives the reed 5 to move down, thereby driving the light blocking plate 50 to move down, and at the same time, the reed 5 is compressed to generate an elastic shape; When the pressure on the guide core 4 is released, the guide core 4 is driven upward by the elastic restoring force of the reed 5, and at the same time, the light blocking sheet 50 moves upward. Therefore, in the two processes of moving the guide core 4 upward and downward, the reed 5 bounces back and strikes other parts (hereinafter referred to as striking the sounding surface) to make sound, and at the same time, the light blocking sheet 50 also moves upward and downward. So as to block or not block the light between the light-emitting element 71 and the photosensitive element 72, thereby realizing the function of blocking or not blocking the light path between the light-emitting element 71 and the photosensitive element 72 by the light-blocking sheet 50.

Specifically, if the microswitch is a normally closed switch, when the microswitch is in the initial unpressed state, the light blocking sheet 50 is located between the light emitting element 71 and the photosensitive element 72. The light blocking sheet 50 blocks the light emitted by the light-emitting element 71, so that the light-sensitive element 72 cannot receive the light, that is, the light blocking sheet 50 blocks the light path between the light-emitting element 71 and the light-sensitive element 72. At this time, a signal is given to the PCB 6, and this signal is defined as the microswitch off signal, as shown in FIG. 7. When the guide core 4 is pressed down, the downward movement of the reed 5 drives the light blocking plate 50 to move down, and the light blocking plate 50 no longer blocks the light path between the light emitting element 71 and the photosensitive element 72. Then the photosensitive element 72 can normally receive the light emitted by the light-emitting element 71, and at this time, a signal is given to the PCB 6, which is defined as a microswitch on signal.

If the microswitch is a normally open switch, when the microswitch is in the initial unpressed state, the light blocking sheet 50 does not move between the light emitting element 71 and the photosensitive element 72. If the light blocking sheet 50 does not block the light emitted by the light emitting element 71, the light sensitive element 72 receives the light, That is, the light blocking sheet 50 does not block the light path between the light emitting element 71 and the photosensitive element 72, and at this time, a signal is given to the PCB 6, which is defined as a microswitch off signal; When the guide core 4 is pressed down, the downward movement of the reed 5 drives the light-blocking sheet 50 to move down, and the light-blocking sheet 50 moves between the light-emitting element 71 and the photosensitive element 72. The light-blocking sheet 50 blocks the light emitted by the light-emitting element 71, so that the light-sensitive element 72 cannot receive the light. That is, the light blocking sheet 50 blocks the light path between the light-emitting element 71 and the photosensitive element 72, and at this time, a signal is given to the PCB 6, which is defined as a microswitch on signal.

In this embodiment, as shown in FIG. 3, the light emitting diode assembly 7 further includes a pad 73 and two first PIN pins 74 welded to the light emitting element 71 through the pad 73. And two second PIN pins 75 soldered to the photosensitive element 72 through pads 73, and the two first PIN pins 74 and the two second pin pins 75 are electrically connected to the PCB board 6, respectively. Specifically, the two first PIN pins 74 and the two second PIN pins 75 are respectively vertically inserted into the PCB board 6. In this embodiment, the two first PIN pins 74 and the two second PIN pins 75 are copper sheets.

Before assembling the light-emitting tube assembly 7 into the base 11, the two first PIN pins 74 and the two second PIN pins 75 are in a straight state. Firstly, the light-emitting pair tube assembly 7 with a straight first PIN pin 74 and a straight second PIN pin 75 is integrally inserted into the base 11, Then, the two first PIN pins 74 and two second PIN pins 75 are bent to be perpendicular to the bonding pad 73, and finally, the two first PIN pins 74 and two second PIN pins 75 are connected to the PCB board 6. As shown in FIG. 9, electrical connection to the PCB board 6 is achieved. Of course, it is also possible to mount on the PCB board 6 by using a patch. The integral structural design of that light-emitting tube assembly 7 is adopt, so that the light-emitting tube assembly 7 can be directly inserted and assemble into the base 11, which is particularly convenient for automatic assembly and improves the convenience and efficiency of assembly.

In order to facilitate that downward movement of the light blocking sheet 50 to block the light between the light emit element 71 and the photosensitive element 72, As shown in FIG. 3, the bonding pad 73 in this embodiment is provided with a relief port 730 which is located between the light-emitting element 71 and the photosensitive element 72 and through which the light-blocking sheet 50 passes. The downward movement of the light blocking plate 50 is relieved by the relief port 730.

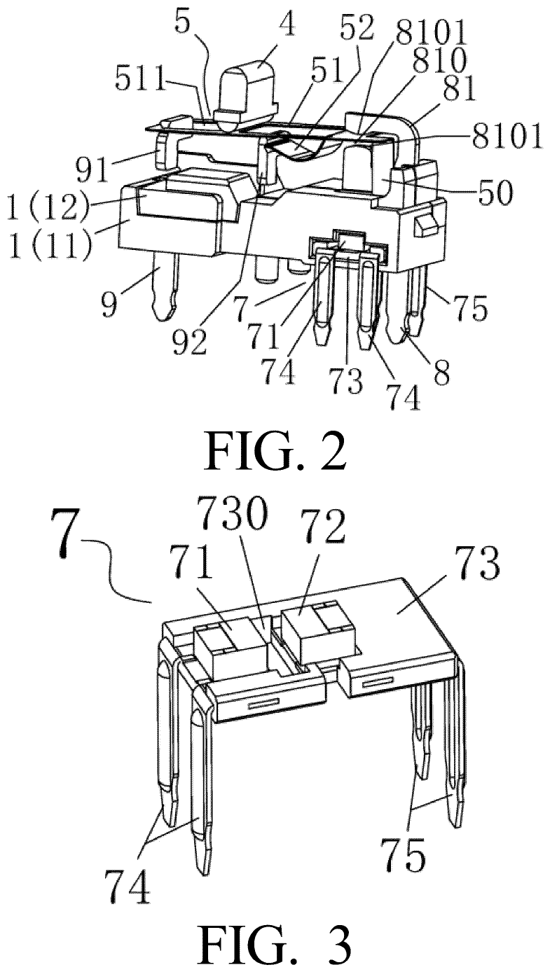

In this embodiment, as shown in FIGS. 2 and 5, a mounting cavity 10 is formed in the base 11. The light-emitting pair tube assembly 7 is arranged in the mounting cavity 10, and two sides of the mounting cavity 10 are respectively provided with a through hole 101 for the first PIN pin 74 and the second PIN pin 75 to pass through. Due to the matching structure design of the base 11, when assembling, the light-emitting tube assembly 7 can be directly inserted from one side through hole 101. Then, the leaked first PIN pin 74 and second PIN pin 75 are bent, which is convenient and quick to operate, and obviously improves the assembly convenience and efficiency.

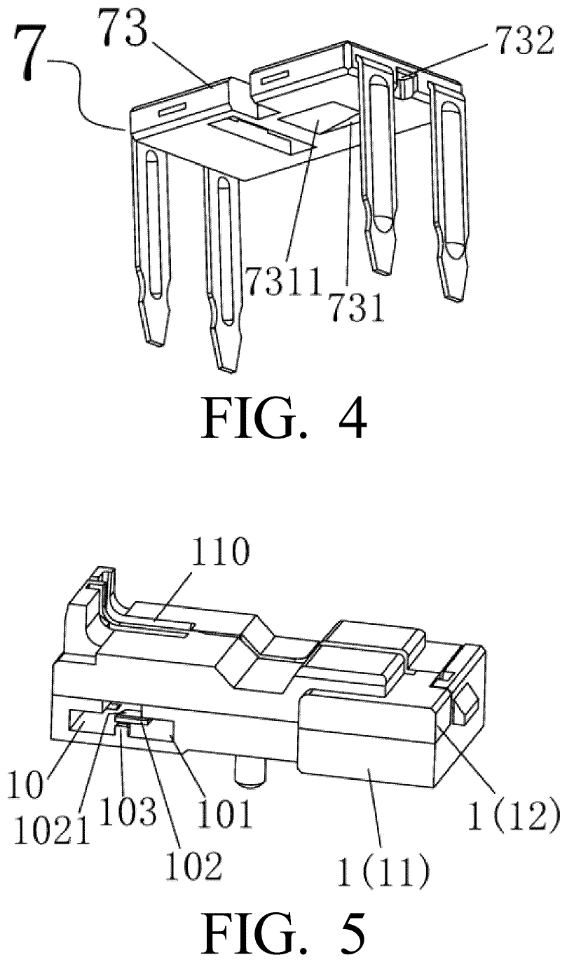

In order to improve the stability of the light-emitting diode assembly 7 after it is assembled into the base 11, as shown in FIGS. 4 and 5, an inner limiting slot 731 is formed at the bottom of the bonding pad 73 in this embodiment. An inner limiting protrusion 102 which is locked into the inner limiting slot 731 is convexly arranged in the mounting cavity 10. When the light-emitting tube assembly 7 is inserted into the mounting cavity 10 of the base 11, the inner limiting protrusion 102 meets the inner limiting slot 731, It is directly clamped into the inner limit slot 731 to limit the welding pad 73, that is, to position the light-emitting tube assembly 7, so that the light-emitting tube assembly 7 can be stably assembled into the base 11.

Meanwhile, in order to facilitate the assembly operation, in this embodiment, a lower guide inclined plane 1021 is formed on one side of the inner limit protrusion 102, and an upper guide inclined plane 7311 matching with the lower guide inclined plane 1021 is formed in the inner limit clamping groove 731. The upper guide inclined plane 7311 is matched with the lower guide inclined plane 1021, which not only plays a guiding role in the insertion action, but also facilitates the direct contact between the upper guide inclined plane 7311 and the lower guide inclined plane 1021 after assembly, thus improving the stability of the overall structure after assembly.

When the pad 73 is inserted from the through hole 101 on one side of the base 11, in order to prevent the pad 73 from penetrating out of the mounting cavity 10 due to excessive force, In this embodiment, a one-side limiting slot 732 is formed at one end of the bonding pad 73, and a one-side limiting protrusion 103 is formed at the one-side through hole 101 of the mounting cavity 10 to be locked into the one-side limiting slot 732. When the side limit slot 732 meets the side limit protrusion 103, the side limit protrusion 103 is directly clamped into the side limit slot 732, That is, the pad 73 is directly blocked by the side limiting protrusion 103 to prevent the pad 73 from penetrating out of the mounting cavity 10, which makes the assembly more accurate and convenient.

In this embodiment, when the microswitch is a normally closed switch, a light-transmitting hole 501 is formed in the light-blocking sheet 50, as shown in FIG. 1. When the microswitch is in the initial unpressed state, the light blocking sheet 50 is located between the light emitting element 71 and the photosensitive element 72. The light blocking sheet 50 blocks the light emitted by the light-emitting element 71, so that the light-sensitive element 72 cannot receive the light, that is, the light blocking sheet 50 blocks the light path between the light-emitting element 71 and the light-sensitive element 72. At this time, a signal is given to the PCB 6, which is defined as the microswitch off signal; When the guide core 4 is pressed down, the downward movement of the reed 5 drives the light blocking plate 50 to move down, So that the light-transmitting hole 501 moves between the light-emitting element 71 and the photosensitive element 72, That is, the light emitted by the light-emitting element 71 can be received by the photosensitive element 72 through the light-transmitting hole 501, and at this time, a signal is given to the PCB 6, which is defined as a microswitch on signal.

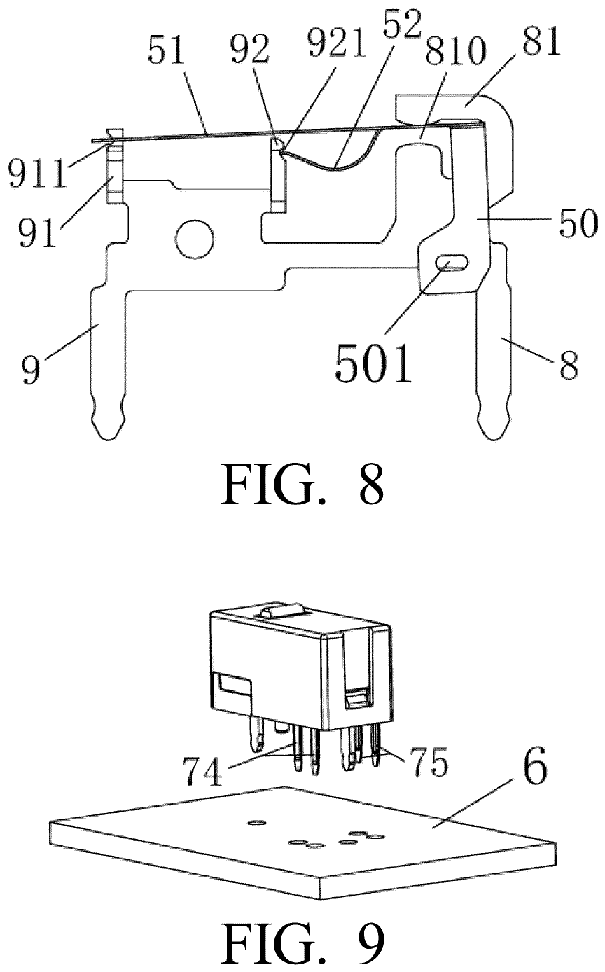

In order to control the up-and-down moving strokes of the reed 5 and the light blocking plate 50, as shown in FIGS. 2 and 8, In this embodiment, a first fixed terminal 8 is arranged on the base 11, and the lower end of the first fixed terminal 8 penetrates through the lower end surface of the base 11. The first fixed terminal 8 is formed with a limiting part 81 located at the upper end face of the base 11, A side opening 810 for inserting one end of the reed 5 and moving up and down is formed in the limiting part 81. A tapping sound surface 8101 is formed at the upper and lower ends of the side opening 810, respectively.

Preferably, the height of the side opening 810 is equal to the height of the light-transmitting hole 501. Specifically, the height can be about 0.35 mm. Based on the structural design of the limiting part 81 with the side opening 810, and specifically defined that the height of the side opening 810 is equal to the height of the light-transmitting hole 501, Controlling the up-and-down moving stroke of the reed 5, that is, controlling the up-and-down moving stroke of the light-blocking plate 50, makes the signal generation between the light-emitting element 71 and the photosensitive element 72 more accurate.

At the same time, in the two processes of the guide core 4 moving up and down, the reed 5 rebounds to reset the tapping sound surfaces 8101 at the upper and lower ends of the tapping side opening 810 to sound, thus realizing the pressing sound function. Compared with the split structure, or the structural design of connecting the two with other structures, the structural design of connecting the reed 5 and the light-blocking sheet 50 into a whole in this embodiment makes the sound emitted by knocking consistent and clearer.

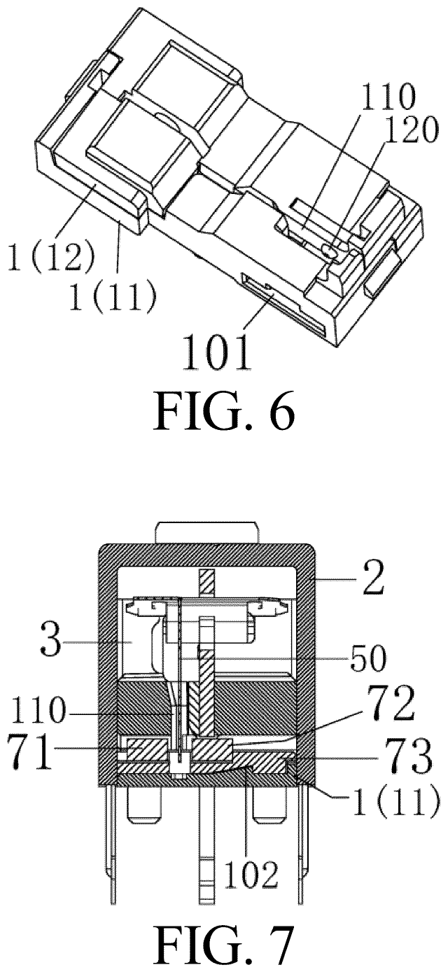

In order to facilitate the smooth movement of the light blocking plate 50 up and down, as shown in FIG. 6, In this embodiment, the base 11 and the base 12 are combined to form a longitudinal slot 110, which is connected to the installation cavity 10 and is used for the light blocking plate 50 to be inserted longitudinally. Meanwhile, the base 12 is provided with a limit bump 120 located on the inner wall of the longitudinal slot 110. Due to the arrangement of the limiting bumps 120, the light-blocking sheet 50 is supported and limited, which can effectively prevent the light-blocking sheet 50 from swinging from side to side and play a limiting role, and at the same time, play a certain guiding role in the up-and-down movement of the light-blocking sheet 50, thereby improving the stability of the up-and-down movement of the light-blocking sheet 50.

As for the specific structure of the reed 5, as shown in FIGS. 2 and 8, the reed 5 in this embodiment mainly consists of an elastic sheet 51 and a tongue sheet 52 integrally formed at the lower part of the elastic sheet 51 and bent downward, and the light blocking sheet 50 is formed by bending and extending one side edge of the elastic sheet 51 downward. For the specific installation of the reed 5, a second fixed terminal 9 is arranged on the base 12, and the lower end of the second fixed terminal 9 penetrates through the lower end surface of the base 11, and a first connecting part 91 and a second connecting part 92 located on the upper end surface of the base 12 are formed on the second fixed terminal 9. The elastic sheet 51 is provided with a connecting opening 511 through which the first connecting part 91 passes. The outer side of the first connecting part 91 is provided with a first clamping groove 911 for clamping the inner wall of the connecting opening 511. The outer side of the second connecting part 92 is provided with a second clamping groove 921 for the end of the tongue piece 52 to be clamped. The reed 5 is limited by the first clamping groove 911 of the first connecting part 91 and the second clamping groove 921 of the second connecting part 92, so that when the guide core 4 is pressed and moved up and down, The reed 5 can be elastically deformed within a certain range, which can not only drive the light blocking plate 50 to move up and down, but also provide a stable elastic restoring force for the guide core 4.

In this embodiment, as shown in FIG. 10, a strip-shaped clamping groove 111 is formed on the base 11, and a strip-shaped clamping bar 121 is formed at the bottom of the base 12 to be clamped into the strip-shaped clamping groove 111. When assembling, the strip-shaped clamping strip 121 of the base 12 is directly clamped into the strip-shaped clamping groove 111, so that the base 12 is assembled on the base 11, and the assembly is convenient and quick. At the same time, two opposite ends of the base 11 are respectively provided with a limit stopper 112, and two opposite ends of the base 12 are respectively provided with a limit notch 122 into which the limit stopper 112 is embedded. After assembly, the limit stoppers 112 are clamped into the limit notches 122 from both ends to limit the base 12, so that the stability of the base 12 after assembly on the base 11 is higher.

The above is only the preferred embodiment of this utility model, and it does not limit the technical scope of this utility model. Therefore, other structures obtained by adopting the same or similar technical features as the above embodiments of this utility model are within the protection scope of this utility model.

1. A photoelectric microswitch comprises a mounting base and a cover covering the mounting base, wherein the cover covers the mounting base to form an accommodating cavity; a guide core and a reed are arranged in the accommodating cavity, and the reed is positioned below the guide core, and the upper end of the guide core penetrates through the cover for pressing; and the photoelectric microswitch is characterized in that the mounting base comprises a base and a base arranged on the base, and a light-emitting pair tube assembly electrically connected to a PCB board is arranged in the base. The reed is installed on the base, and a light-blocking sheet for blocking the light between the light-emitting element and the photosensitive element is extended downwards, and the reed and the light-blocking sheet are connected into a whole.

2. The photoelectric microswitch according to claim 1 is characterized in that an installation cavity is formed in the base, the light-emitting tube assembly is arranged in the installation cavity, and the base and the base are combined to form a longitudinal slot which is communicated with the installation cavity and is used for vertically and movably inserting the light shield.

3. The photoelectric microswitch according to claim 2 is characterized in that the light-emitting tube assembly further comprises a pad, two first PIN pins welded to the light-emitting element through the pad, and two second PIN pins welded to the photosensitive element through the pad, and the two first PIN pins and the two second PIN pins are electrically connected to the PCB board respectively.

4. The photoelectric microswitch according to claim 3 is characterized in that the two first PIN pins and the two second PIN pins are respectively vertically inserted into the PCB.

5. The photoelectric microswitch according to claim 3, characterized in that the pad is provided with a yielding opening which is located between the light-emitting element and the photosensitive element and through which the light-blocking plate passes.

6. The photoelectric microswitch according to claim 3 is characterized in that two sides of the mounting cavity are respectively provided with a through hole for the first PIN pin and the second PIN pin to pass through.

7. The photoelectric microswitch according to claim 3 is characterized in that an inner limit slot is formed at the bottom of the bonding pad, and an inner limit protrusion which is clamped into the inner limit slot is convexly arranged in the mounting cavity.

8. The photoelectric microswitch according to claim 7 is characterized in that a lower guide inclined plane is formed at one side of the inner limit projection, and an upper guide inclined plane matched with the lower guide inclined plane is formed in the inner limit clamping groove.

9. The photoelectric microswitch according to claim 6 is characterized in that a one-side limit slot is formed at one end of the bonding pad, and a one-side limit protrusion is formed at the one-side penetration of the mounting cavity.

10. The photoelectric microswitch according to claim 2 is characterized in that a limit bump located on the inner wall of the longitudinal slot side is arranged on the base.

11. The photoelectric microswitch according to claim 1 is characterized in that a strip-shaped clamping groove is formed on the base, and a strip-shaped clamping strip clamped in the strip-shaped clamping groove is formed at the bottom of the base.

12. The photoelectric microswitch according to claim 1 is characterized in that two opposite ends of the base are respectively provided with a limit stopper, and two opposite ends of the base are respectively provided with a limit notch for embedding the limit stopper.

13. The photoelectric microswitch according to claim 1 is characterized in that a first fixed terminal is arranged on the base, and the lower end of the first fixed terminal penetrates through the lower end surface of the base, and a limit part located on the upper end surface of the base is formed on the first fixed terminal, and a side opening for one end of the reed to be inserted and move up and down is formed on the limit part, and a tapping sound surface is formed at the upper end and the lower end of the side opening respectively.

14. The photoelectric microswitch according to claim 13 is characterized in that a light-transmitting hole is formed on the light-blocking sheet.

15. The photoelectric microswitch according to claim 14, wherein the height of the side opening is equal to the height of the light-transmitting hole.

16. The photoelectric microswitch according to claim 1 is characterized in that the reed is mainly composed of an elastic piece and a tongue piece integrally formed at the lower part of the elastic piece and bent downward, and the light blocking piece is formed by bending and extending one side edge of the elastic piece downward.

17. The photoelectric microswitch according to claim 16 is characterized in that a second fixed terminal is arranged on the base, and the lower end of the second fixed terminal penetrates through the lower end surface of the base, and a first connecting part and a second connecting part located on the upper end surface of the base are formed on the second fixed terminal; The elastic sheet is provided with a connecting opening for the first connecting part to pass through, the outer side of the first connecting part is provided with a first clamping groove for clamping the inner wall of the connecting opening, and the outer side of the second connecting part is provided with a second clamping groove for clamping the end of the tongue piece.
